(19) United States
(12) Patent Application Publication
(10) Pub. No.: US 2007/0242715 A1
(43) Pub. Date: Oct. 18, 2007

(54) MODE AND POLARIZATION CONTROL IN VCSELS USING SUB-WAVELENGTH STRUCTURE

(76) Inventors: Johan Gustavsson, Asa (SE); Asa Haglund, Asa (SE); Anders Larsson, Billdal (SE); Josip Vukusic, Goteborg (SE)

Correspondence Address: HARNESS, DICKEY & PIERCE, P.L.C., P.O. BOX 8910, RESTON, VA, 20195, US

(21) Appl. No.: 11/379,202

(22) Filed: Apr. 18, 2006

(51) Int. Cl. H01S 5/00

(52) U.S. Cl. 372/45.01

(57) ABSTRACT

This invention relates to a vertical-cavity surface-emitting laser (VCSEL) comprising a bottom mirror structure, a top mirror structure, an active layer sandwiched between the top mirror structure and the bottom mirror structure; and at least one asymmetric sub-wavelength structure arranged in on or at least adjacent to the mirror structure of said VCSEL so as to create a polarization dependent mirror reflectivity from said mirror structure.

### TECHNICAL FIELD

The present invention relates to vertical-cavity surface-emitting lasers and more particular to such lasers having a locally defined sub-wavelength structure for transverse mode and polarization control.

### BACKGROUND OF THE INVENTION

The vertical-cavity surface-emitting laser (VCSEL) is a well established light source in short distance fiber-optic links and interconnects. There is a definite scope for further and more demanding applications, such as in spectroscopy, laser printing, optical storage and longer distance communication. Improvement of laser properties for specific applications would probably yield a larger commercial impact of the VCSEL. For example, in the above-mentioned applications a single mode output power of several milliwatts is often needed, and frequently with a stable linear polarization as an additional requirement.

Due to the relative large transverse extent in combination with a symmetric geometry and isotropic material properties, the VCSEL tends to lase in several transverse modes with an unpredictable state of polarization. The linear polarization states of the individual modes lie in the plane of the epitaxial layers, and due to the electro-optic effect they are normally polarized in the [001] or the [0-11] crystallographic direction. However, the polarization often randomly switches between these two directions because of temperature, injection current, and optical feed-back effects.

Several methods have been developed to obtain single mode emission and/or a stable polarization state from VCSELs, but unfortunately many of these methods negatively affects other important laser characteristics such as the threshold current, differential resistance, and beam quality.

The article entitled “Control of vertical-cavity laser polarization with anisotropic transverse cavity geometries” by K. D. Choquette et al. (Photonics Technology Letters, vol. 6, no. 1, pp. 40-42, January 1994) describes the use of small asymmetric cavity geometries, e.g. rhombus-shaped and dumbbell-shaped, to achieve single mode and polarization stable VCSELs. Special care has to be taken when designing these cavities in order to minimize non-radiative recombination and diffraction losses.

U.S. Pat. No. 6,683,898 provides a method for controlling the mode and polarization state in VCSELs by using photonic band gap structures. If deeply etched photonic crystal structures are used the current injection can be obstructed, resulting in a high differential resistance. Scattering loss, diffraction loss, and non-radiative surface recombination at the etched photonic band gap structures can also affect the laser performance.

The article “Polarization-stable oxide-confined VCSELs with enhanced single-mode output power via monolithically integrated inverted grating reliefs” by J. M. Ostermann et al. (IEEE Journal of Selected Topics in Quantum Electronics, vol. 11, no. 5, pp. 982-989, September/October 2005) describes the use of a locally etched surface grating with a period larger than the optical wavelength in the material. These periods can result in diffraction related losses and beam degradation and the laser performance become very sensitive to the grating geometry and an optimized design therefore requires rigorous electromagnetic modeling.

### SUMMARY OF THE INVENTION

The present invention uses a sub-wavelength asymmetric polarizing structure, e.g. a grating i.e. a grating with a grating period smaller than the light wavelength in the material, to achieve polarization control and it could also be locally defined to simultaneously achieve transverse mode control. The advantage of using a sub-wavelength grating compared to a larger grating period is that the diffraction related losses and beam degradation are minimized. Moreover, the effective index nature of the sub-wavelength grating will also render the performance rather insensitive to the exact shape and geometry of the grating.

The principle behind the present invention is to control the mode selection and polarization state by introducing a mode and polarization dependent mirror reflectivity/loss in a VCSEL. This is achieved by using a locally defined asymmetric sub-wavelength structure.

In particular the invention provides a vertical-cavity surface-emitting laser (VCSEL) comprising: a bottom mirror structure; a top mirror structure; and an active layer sandwiched between the top mirror structure (100) and the bottom mirror structure. The VCSEL is characterized in that at least one asymmetric sub-wavelength structure is arranged in or at least adjacent to the mirror structure of the VCSEL so as to create a polarization dependent mirror reflectivity from the mirror structure.

Said asymmetric sub-wavelength structure is preferably a grating with a grating period that is smaller than the light wavelength in the grating material.

It is preferred that the grating comprises lines or elongated dots.

It is preferred that said asymmetric sub-wavelength structure is arranged in, or on top of, or on the bottom of the top mirror structure of the VCSEL.

However, said sub-wavelength structure can alternatively be arranged in, or on top of, or at the bottom of the bottom mirror structure of the VCSEL.

Said asymmetric sub-wavelength structure can be locally defined in or adjacent to an area of the VCSEL wherein a transverse mode has a large intensity, so as to achieve transverse mode control.

An epitaxial layer in the epitaxial structure of said VCSEL can be partly oxidized to yield an oxide aperture 300; in which case it is preferred that the diameter or cross-section of the grating region is smaller than the diameter or cross-section of the oxide aperture 300.

Said asymmetric sub-wavelength structure can be defined in a substantially λ/4-thick layer arranged on the top mirror structure, or in a substantially λ/4-thick layer arranged on the bottom mirror structure of said VCSEL.

Said asymmetric sub-wavelength structure can be defined in a top layer of the top mirror structure, or in a bottom layer of the bottom mirror structure.

The duty cycle of the of said grating period is preferably arranged so that a large anisotropy in effective index is achieved between a direction perpendicular to the grating lines or grating dots and a direction parallel to the grating lines or grating dots.

Said sub-wavelength structure is preferably made of one of semiconductor material, dielectric material or metal material.

In particular, the invention provides for of a vertical-cavity surface-emitting laser (VCSEL) that can be used in spectroscopy applications, optical communication, optical data storage, laser printers, optical mouse, free-space interconnects, measurements techniques, which VCSEL comprises: a bottom mirror structure; a top mirror structure; and an active layer sandwiched between the top mirror structure and the bottom mirror structure; and

at least one asymmetric sub-wavelength structure arranged in or at least adjacent to the mirror structure of said VCSEL so as to create a polarization dependent mirror reflectivity from said mirror structure.

In particular, the invention provides for of a vertical-cavity surface-emitting laser (VCSEL) that can be used in spectroscopy applications, optical communication, optical data storage, laser printers, optical mouse, free-space interconnects, measurements techniques, which VCSEL comprises: a bottom mirror structure; a top mirror structure; an active layer sandwiched between the top mirror structure and the bottom mirror structure; and

at least one asymmetric sub-wavelength structure (106; 200; 301; 304) locally arranged in or at least adjacent to the mirror structure of said VCSEL so as to create a polarization and transverse mode dependent mirror reflectivity from said mirror structure.

These and other aspects of the invention will be apparent from and elucidated with reference to the embodiments described hereinafter.

### BRIEF DESCRIPTION OF THE DRAWINGS

In the following the invention will be described in a non-limiting way and in more detail with reference to exemplary embodiments illustrated in the enclosed drawings, in which:

FIG. 1 illustrates an embodiment according to the present invention;

FIGS. 2(a)-2(c) illustrate schematic top views of three asymmetric sub-wavelength structures that can be used for polarization control according to embodiments of the present invention;

FIGS. 3(a)-3(b) illustrate schematic top and cross-sectional views of two VCSEL designs according to embodiments of the present invention;

FIG. 4 illustrate two different designs to select two different transverse modes according to embodiments of the present invention;

FIGS. 5(a)-5(b) illustrate schematic top and cross-sectional views of two VCSEL designs according to embodiments of the present invention;

FIGS. 6(a)-6(b) show the calculated polarization dependent modal loss as a function of grating duty cycle and depth for two designs according to an embodiment of the invention;

FIGS. 7(a)-7(b) show measured output power (polarization resolved) and OPSR versus current, optical spectra, and far-field, for two VCSELs according to an embodiment of the invention;

### DETAILED DESCRIPTION OF PREFERRED EMBODIMENTS

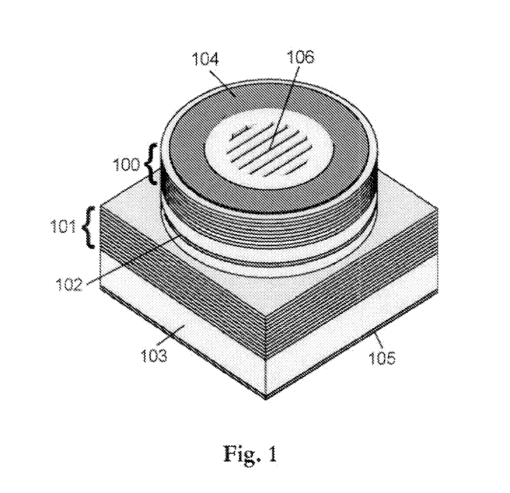

FIG. 1 illustrates an embodiment of the present invention. The VCSEL consists of a top reflector 100 and a bottom reflector 101 which defines the cavity, and an active region 102 sandwiched in between the two reflectors 100, 101. The VCSEL layer structure is normally grown on an appropriate substrate 103 by well-known techniques such as metal organic vapour phase epitaxy or molecular beam epitaxy. In the processing of VCSELs from the layer structure electrical contacts 104, 105 can be applied if the VCSEL is going to be electrically pumped. There are numerous schemes for the contact layout where only one example is shown in FIG. 1. In the present invention, single mode and polarization stable VCSELs are achieved by creating a mode and polarization dependent mirror loss through the use of a specially designed sub-wavelength structure, which in the figure is illustrated with a grating 106, which will be further described below.

The sub-wavelength structure act as an effective index medium, and by an asymmetric design, a high contrast in effective index can be achieved between two orthogonal polarization states. The sub-wavelength structure is included in the mirror structure of the VCSEL and as a result the two orthogonal polarization states will experience two different mirror reflectivities. For one polarization state, the reflectivity contribution from the sub-wavelength structure will be more in phase with the rest of the reflections in the mirror stack, producing a high mirror reflectivity, while for the orthogonal polarization state, the contribution will be more out-of-phase, reducing the total mirror reflectivity. As a result, the polarization state with a lower mirror reflectivity will be suppressed. Thus, a polarization stable laser can be achieved by applying an asymmetric sub-wavelength structure over the emission window of the laser.

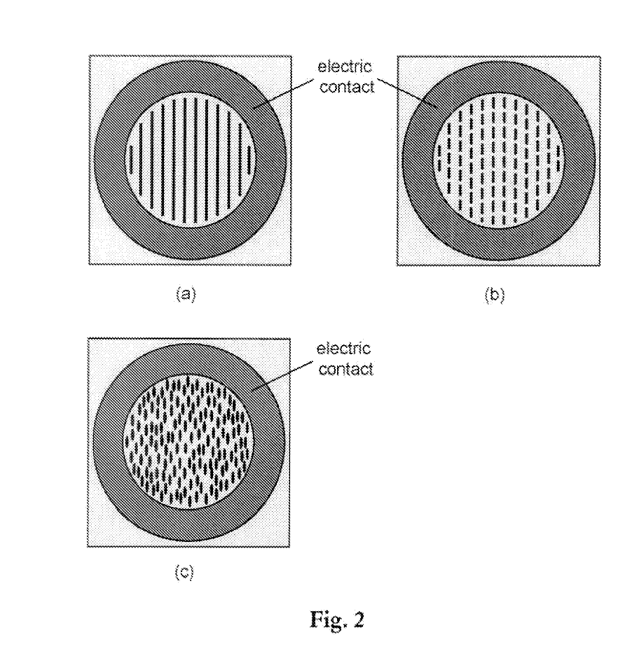

Many different asymmetric sub-wavelength structures can be used to achieve polarization control, where two examples are given in FIG. 2. In the examples in FIG. 2 the sub-wavelength structures have been implemented in the form of a grating having a grating period smaller than the light wavelength in the grating material. The grating may comprise substantially equidistant lines or lines that are arranged at different mutual distances, provided that said distances are smaller than the light wavelength in the grating material. It is preferred that the lines extend substantially in parallel to each other. However, at least a sub-set of the set of grating lines may extend with an angle with respect to another sub-set of grating lines. The grating lines may be continuous or discontinuous, e.g. a discontinuous line formed by dots or a plurality of short lines as can be seen in FIG. 2(a). In fact, the grating may comprise any asymmetric sub-wavelength structure of lines or dots that are arranged so as to accomplish a polarization dependent mirror reflectivity in a VCSEL. The grating may e.g. comprise elongated dots of a suitable shape or shapes as shown in FIG. 2(c), wherein at least a sub-set of the dots are arranged in substantially the same direction so that the spatial distance between adjacent dots in the sub-set is smaller than the light wavelength in the grating material so as to form an anisotropic structure.

The sub-wavelength structure can be made of any suitable material for example semiconductor material, dielectrics and metals. It can be defined in the top layer/layers of a mirror structure and/or in layers deposited on top of mirror structure and/or defined in one or several of the mirror layers further down in the mirror stack in the top and/or bottom mirror.

The asymmetric sub-wavelength structure can be applied to emission wavelengths between 100 nm and 10 μm. If the asymmetric structure is in the form of a grating as suggested above, the period should be smaller than the light wavelength in the grating material. For example, if the emission wavelength is 850 nm and the effective index of refraction of the grating structure is 3.5, the light wavelength in the material becomes 850/3.5=243 nm, i.e. the period of the grating should be smaller than 243 nm.

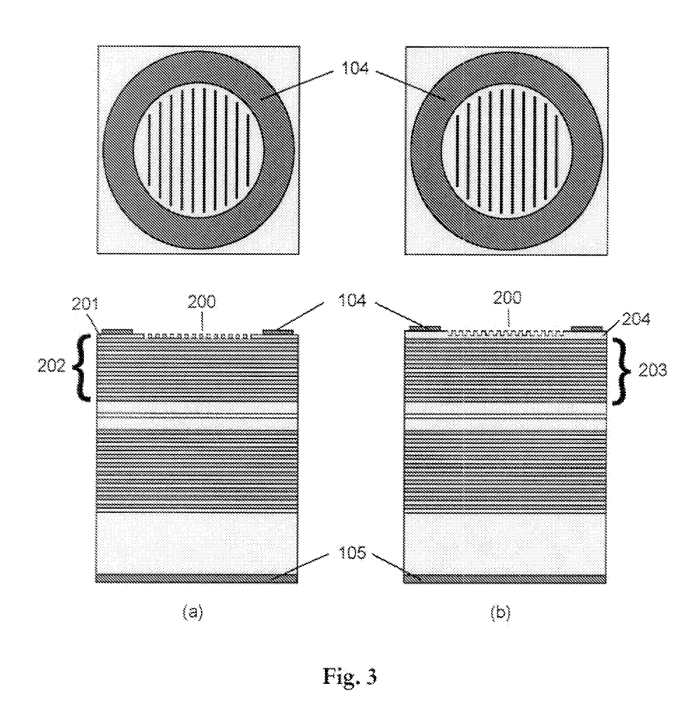

In FIG. 3 two ways are illustrated to incorporate an asymmetric sub-wavelength structure to achieve polarization control. In FIG. 3(a) and FIG. 3(b) the sub-wavelength structure consists of a grating 200 with a grating period smaller than the light wavelength in the grating material.

In FIG. 3(a), the structure is defined in the top layer 201 of a high reflectivity mirror 202. The polarization state parallel to the grating lines will then experience an effective index from the structure that is close to the index of the grating material. The grating structure 200 is thus experienced as very similar to the original mirror structure and therefore the mirror reflectivity is still high. The polarization state orthogonal to the grating lines will, on the other hand, experience an effective index close to air, and thereby a reduced total mirror reflectivity. This favours the polarization state parallel to the grating lines and suppresses the orthogonal polarization state.

In FIG. 3(b) the grating 200 is defined in an extra quarter-wavelength-thick layer 204 added on top of the mirror structure 203. Before the definition of the grating 200, the mirror reflectivity is low since reflections from the layer 204 are out-of-phase with reflections further down in the mirror stack. However, after the grating 200 has been included, modes with polarization state orthogonal to the grating lines experience the grating structure having an effective index close to air and the out-of-phase reflections are thereby reduced and a high mirror reflectivity is achieved. The polarization state parallel to the grating lines will experience an effective index close to the effective index of the grating material and the out-of-phase reflections and thereby the low mirror reflectivity is therefore maintained in this case. Thus, the polarization state orthogonal to the grating lines will be favoured while the polarization state parallel to the grating lines is suppressed.

FIG. 3 only shows two different ways to incorporate an asymmetric sub-wavelength structure for polarization control, in this case in the form of a grating in the top layer of the VCSEL structure. As pointed out earlier, many different asymmetric structures can be used and could be defined in the top layer of the structure or further down in the mirror stack of the top and/or bottom mirror. The grating structure does not necessarily have to be defined in semiconductor material but can also be defined in other suitable materials such as dielectrics or metals.

If the asymmetric sub-wavelength structure is applied locally, not only polarization control but also mode control can be achieved. In the region where a sub-wavelength structure is defined the mirror reflectivity is affected. By defining the structure locally, in areas where a certain transverse mode/modes has a large intensity, this mode/modes is mainly affected and can be suppressed or enhanced, thus a mode selectivity can be achieved.

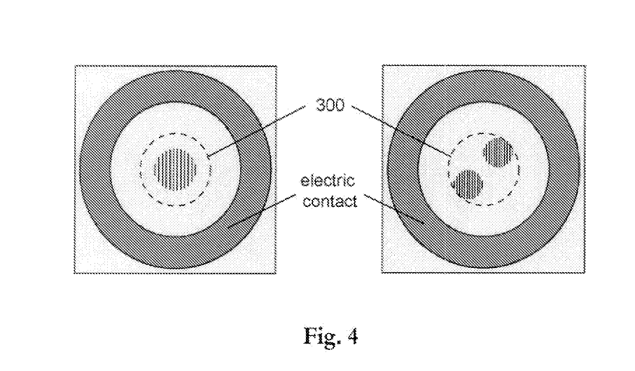

FIG. 4 shows two different designs to select two different transverse modes; in these two examples the mirror reflectivity is increased in the region of the grating and the mode with high intensity in the grating region is selected while the other transverse modes are suppressed.

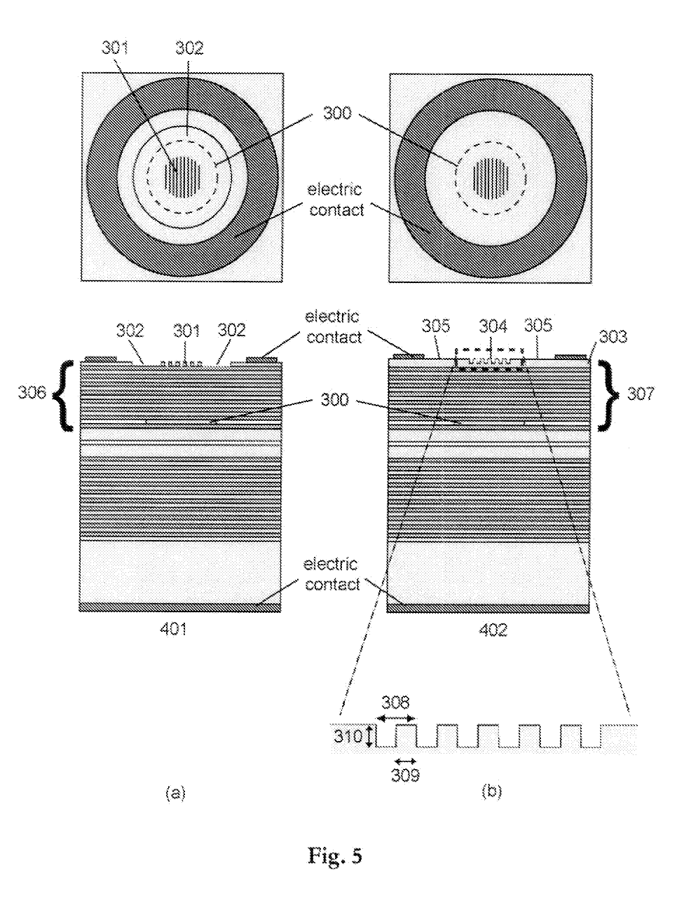

FIG. 5 illustrates two ways to achieve a combined mode and polarization control by applying an asymmetric sub-wavelength structure in the form of a grating in the top layer of the VCSEL structure. In both these cases the fundamental mode is selected and the other transverse modes are suppressed. To achieve good control over the transverse extension of the modes an epitaxial layer in the epitaxial structure of the VCSEL has been partly oxidized to yield an oxide aperture 300 and thereby a waveguide. There are also many other methods to achieve good control over the transverse extensions of the modes and the present invention can be applied to any of these to improve the single mode and polarization stable output power.

In FIG. 5(a) the fundamental-mode with a polarization state parallel to the grating lines, LP01-E_{∥}, is favoured, while in FIG. 5(b) it is the fundamental mode with polarization state perpendicular to the grating lines, LP01-E_{⊥}. In both cases a quarter-wavelength-deep surface depression is etched in a circular area concentric with the oxide aperture 300. The depth of the surface structure does not have to be quarter-wavelength-deep, but can be any depth that yields a large enough difference in mirror loss between the two polarization states and the different transverse modes. In the conventional way (a) a standard epitaxial VCSEL structure is used, and the depression consists of an inner grating region 301 and an outer totally etched region 302, not necessarily with the same depth. In the inverted way (b) an extra quarter-wavelength-thick topmost layer 303 is added to the epitaxial structure, and the depression consists only of a grating region 304. For both cases the top mirror loss is high in the area just outside the grating region 302, 305 because the reflections at the semiconductor-air interface are here in anti-phase with the rest of the reflections further down in the mirror stack 306, 307. This is utilized to provide the fundamental-mode selection. In an oxide-confined VCSEL the transverse-modes are guided by the oxide aperture 300. By having a grating region 301, 304 diameter or cross-section that is smaller than the oxide aperture 300 diameter the intensity distribution of the higher-order modes will have a larger overlap with this high-loss region compared to the fundamental-mode, and therefore experience a higher modal loss. Typically for a normal VCSEL structure, the diameter of the grating region 301, 304 should be half the diameter of the oxide aperture 300 to achieve a high fundamental-mode selection. The polarization selection is provided by the grating region 301, 304. Since the optical field has a wavelength larger than the grating period 308 it experiences the sub-wavelength grating as an anisotropic homogenous medium, having effective indices that are higher than the index of air but lower than the index of the grating material. The anisotropic effective index can be tailored by the duty cycle (ridge 309 to period 308 ratio) such that in the direction perpendicular to the grating lines it is close to the index of air and in the parallel direction it is close to the index of the grating material. Thus, relatively strong anti-phase reflections can effectively be produced by the grating 301, 304 for the polarization state perpendicular to the grating lines in case (a) and parallel to the grating lines in (b), while in-phase reflections are effectively produced for the corresponding orthogonal polarization states, which therefore are favoured.

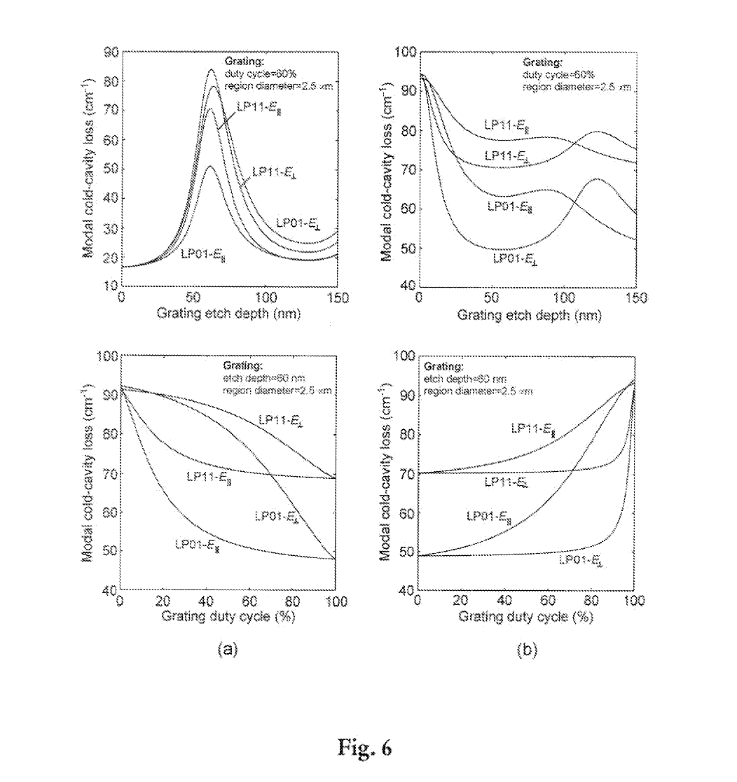

The calculated polarization dependent modal loss for the conventional structure 401 and the inverted structure 402 are shown in FIGS. 6(a) and (b) respectively. For a depth 310 of 60 nm and a duty cycle of 60% a >20 cm⁻¹ mode selectivity, i.e. loss difference between the fundamental-mode (LP01) and the first higher-order mode (LP11), and simultaneously a 15 cm⁻¹ polarization selectivity, i.e. loss difference between LP01-E_{∥} and LP01-E_{⊥}, can be achieved in both cases. In the conventional 401 technique LP01-E_{∥} is favoured, while in the inverted 402 technique it is LP01-E_{⊥}. Further, in the conventional 401 technique the polarization selectivity is larger than the mode selectivity while in the inverted 402 technique it is the opposite. The dependence on depth 310 and duty cycle is also different between the conventional 401 and the inverted 402 technique. In the inverted 401 case a depth variation of ±20 nm from the targeted depth of 60 nm will still maintain the high values of mode and polarization selectivity without significantly increasing the loss for the favoured LP01-E_{⊥}, while in the conventional 402 case the dependence on depth 310 is much stronger and the loss for the favoured fundamental mode also changes dramatically with depth 310. Thus, a small performance variation in threshold current, output power, and mode and polarization selectivity over a broad range of depths 310 can only be anticipated for the inverted 402 technique. Comparing the modal loss as a function of duty cycle for the conventional 401 and inverted 402 technique it can be seen that for the conventional 401 case a high mode selectivity of >15 cm⁻¹ and a polarization selectivity of 10 cm⁻¹ can be obtained within a larger range of duty cycles. However, the modal loss for the favoured mode has a much stronger duty cycle dependence than in the inverted 402 case, which leads to a larger variation in threshold current, slope efficiency, resonance frequency etc. If only a small performance variation is allowed the duty cycle range for the inverted technique 402 is much larger than for the normal 401 technique. In other words, the inverted sub-wavelength surface grating technique is preferable since a large mode and polarization selectivity can be achieved over a broad range of depths and duty cycles without negatively affecting the performance, which in turn facilitates the fabrication.

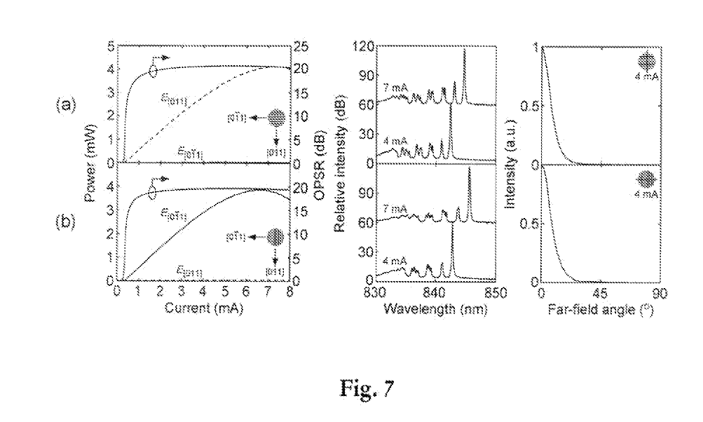

FIG. 7 shows measured polarization resolved output power, optical spectrum, and far-field for two fabricated VCSELs with a sub-wavelength surface grating from an inverted 402 epitaxial structure. Both VCSELs have an oxide aperture 300 diameter of 4.5 μm and a grating region diameter 304 of 2.5 μm. The grooves are oriented in the [0-11] crystallographic direction in (a) and the [011] direction in (b), and the duty cycle is 60% in both cases. The two lasers are single mode and polarization stable, i.e. they have a side-mode suppression ratio (SMSR)>30 dB and an orthogonal polarization suppression ratio (OPSR)>20 dB, from threshold up to thermal roll-over. The polarization state is in both cases perpendicular to the grating grooves. The mode selection from the grating was verified by fabricating VCSELs with the same oxide apertures but without any surface gratings. These devices were all multimode having an OPSR that varies unpredictable between 0 and 10 dB from threshold to thermal roll-over. The polarization selection from the grating is verified by fabricating a VCSEL with an ordinary disk-shaped surface relief (duty cycle of 0%). For this device the polarization switches at a drive current twice the threshold current and again close to thermal roll-over. Moreover, when comparing the characteristics of the normal VCSELs with the grating VCSELs no degradation in threshold current, slope efficiency, and beam quality is observed, supporting the idea that the invention can improve some important laser characteristics without degrade other important characteristics.

Applications of these sub-wavelength-structured VCSELs include spectroscopy applications where a single mode and polarization stable VCSEL are of utmost importance to be able to measure a single or several spectroscopic lines. In addition, the sub-wavelength structured VCSELs can be used in optical communication, e.g. as transmitters for local and storage area networks where single mode and polarization stable operation is desired, as well as in optical data storage and optical pumping. Furthermore, the sub-wavelength-structured VCSELs can be used as transmitters in applications where a good beam quality is needed such as in a laser printer, an optical mouse, and a free-space optical interconnect. They can also be used as a transmitter in a number of different measurements techniques which profit from single mode emission and good beam quality such as in Doppler-based and interference-based measurement techniques.

The sub-wavelength grating structure can be formed in a number of different ways. The structure can be defined by nano-imprint, electron beam lithography, or other lithography techniques capable of defining structures in the nanometer range. The structure can then be transferred into the intended material by wet etching or dry etching techniques. Another possibility is to use standard methods for material deposition and lift-off to form the sub-wavelength structure.

It should be noted that the word “comprising” does not exclude the presence of other elements or steps than those listed and the words “a” or “an” preceding an element do not exclude the presence of a plurality of such elements. It should further be noted that any reference signs do not limit the scope of the claims, and that several “means”, “devices”, and “units” may be represented by the same item of hardware.

The above mentioned and described embodiments are only given as examples and should not be limiting to the present invention. Other solutions, uses, objectives, and functions within the scope of the invention as claimed in the below described patent claims should be apparent for the person skilled in the art.

1. A vertical-cavity surface-emitting laser (VCSEL) comprising:
a bottom mirror structure;
a top mirror structure;
an active layer sandwiched between the top mirror structure and the bottom mirror structure; and
at least one asymmetric sub-wavelength structure arranged in or at least adjacent to the mirror structure of said VCSEL so as to create a polarization dependent mirror reflectivity from said mirror structure.

2. A vertical-cavity surface-emitting laser (VCSEL) as defined in claim 1,
wherein the asymmetric sub-wavelength structure is a grating with a grating period that is smaller than the light wavelength in the grating material.

3. A vertical-cavity surface-emitting laser (VCSEL) as defined in claim 2, wherein the grating comprises lines or elongated dots.

4. A vertical-cavity surface-emitting laser (VCSEL) as defined in claim 1, wherein the asymmetric sub-wavelength structure is arranged in, or on top of, or on the bottom of the top mirror structure of the VCSEL.

5. A vertical-cavity surface-emitting laser (VCSEL) as defined in claim 1, wherein the sub-wavelength structure is arranged in, or on top of, or at the bottom of the bottom mirror structure of the VCSEL.

6. A vertical-cavity surface-emitting laser (VCSEL) as defined in claim 1, wherein the asymmetric sub-wavelength structure is locally defined in or adjacent to an area of the VCSEL wherein a transverse mode has a large intensity to achieve transverse mode control.

7. A vertical-cavity surface-emitting laser (VCSEL) as defined in claim 5, wherein an epitaxial layer in the epitaxial structure of the VCSEL has been partly oxidized to yield an oxide aperture and the diameter or cross-section of the grating region is smaller than the diameter or cross-section of the oxide aperture.

8. A vertical-cavity surface-emitting laser (VCSEL) as defined in claim 1, wherein the asymmetric sub-wavelength structure is defined in a substantially λ/4-thick layer arranged on the top mirror structure or in a substantially λ/4-thick layer arranged on the bottom mirror structure of said VCSEL.

9. A vertical-cavity surface-emitting laser (VCSEL) as defined in claim 1, wherein the asymmetric sub-wavelength structure is defined in a top layer of the top mirror structure or in a bottom layer of the bottom mirror structure.

10. A vertical-cavity surface-emitting laser (VCSEL) as defined in claim 1, wherein the duty cycle of the of the grating period is arranged so that a large anisotropy in effective index is achieved between a direction perpendicular to the grating lines or grating dots and a direction parallel to the grating lines or grating dots.

11. A vertical-cavity surface-emitting laser (VCSEL) as defined in claim 1, wherein the sub-wavelength structure is made of one of a semiconductor material, a dielectric material or a metal material.

12. The use of a vertical-cavity surface-emitting laser (VCSEL) in spectroscopy applications, optical communication, optical data storage, laser printers, optical mouse, free-space interconnects, measurements techniques,
which VCSEL comprises:
a bottom mirror structure;
a top mirror structure;
an active layer sandwiched between the top mirror structure and the bottom mirror structure; and
at least one asymmetric sub-wavelength structure arranged in or at least adjacent to the mirror structure of said VCSEL so as to create a polarization dependent mirror reflectivity from said mirror structure.

13. The use of a vertical-cavity surface-emitting laser (VCSEL) in spectroscopy applications, optical communication, optical data storage, laser printers, optical mouse, free-space interconnects, measurements techniques,
which VCSEL comprises:
a bottom mirror structure;
a top mirror structure;
an active layer sandwiched between the top mirror structure and the bottom mirror structure; and
at least one asymmetric sub-wavelength structure locally arranged in or at least adjacent to the mirror structure of said VCSEL so as to create a polarization and transverse mode dependent mirror reflectivity from said mirror structure.
